(19) United States
(12) Patent Application Publication
(10) Pub. No.: US 2002/0192971 A1
(43) Pub. Date: Dec. 19, 2002

(54) Plasma processing apparatus and processing method using the same, and manufacturing method of semiconductor device

(75) Inventor: Shigenori Sakamori, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 09/987,560

(22) Filed: Nov. 15, 2001

(30) Foreign Application Priority Data
Jun. 13, 2001 (JP) 2001-178190 (P)

(51) Int. Cl. H01L 21/302; H01L 21/461

(52) U.S. Cl. 438/710

(57) ABSTRACT

A chamber for plasma processing is provided with an upper electrode and a lower electrode for discharging plasma. The lower electrode also serves as a stage portion on which a semiconductor substrate is rested. The lower electrode is connected via a matching unit to a high-frequency power supply. A ring-shaped holding member is provided for holding the semiconductor substrate rested on the lower electrode. The holding member is formed of quartz containing platinum (Pt). The holding member is exposed to the plasma, and the platinum contained therein is provided into the chamber. The reductive effect of the platinum restricts deposition of reactive products onto the chamber inner wall.

### BACKGROUND OF THE INVENTION

1. Field of the Invention

The present invention relates to a plasma processing apparatus, a processing method using the same apparatus, and a manufacturing method of a semiconductor device. More particularly, the present invention relates to a plasma processing apparatus that suffers less contamination, a processing method using the relevant apparatus, and a manufacturing method of a semiconductor device with reduced contamination.

2. Description of the Background Art

When manufacturing a semiconductor device, a conductive film, for example, is processed to pattern semiconductor elements, interconnections and others. Further, an insulating film such as a silicon oxide film is processed to form, e.g., a contact hole for connection of the interconnections.

One of the apparatuses used for such processing is a plasma processing apparatus. The plasma processing apparatus is provided with a chamber, in which plasma is generated. For example, in order to form a contact hole, a semiconductor substrate on which a silicon oxide film is formed is introduced into the chamber of the plasma processing apparatus and subjected to prescribed plasma processing. For processing of the silicon oxide film, CF₄, C₄F₈ or the like is used as an etching gas, which is rendered into plasma for prescribed etching of the silicon oxide film.

The plasma processing with the conventional plasma processing apparatus, however, has the following problems. CF₄, C₄F₈ or the like is used as the etching gas for the silicon oxide film, as described above. This would cause CFₓ type polymers as reactive products to adhere to an inner wall of the chamber of the plasma processing apparatus during etching.

As the time of subjecting the semiconductor substrate to the processing (or, accumulated processing time) is increased, the thickness of the polymers accumulated on the inner wall of the chamber increases. Such polymers excessively deposited on the inner wall may be stripped off the wall, and the resultant dust particles would disperse and fall on the surface of the semiconductor substrate. This leads to a decrease in the yield of semiconductor devices.

Further, in order to restrict such deposition of the polymers on the inner wall of the chamber, the temperature of the inner wall itself is sometimes increased. This however requires temperature control of the chamber inner wall. The deposition efficiency of the polymers to the inner wall would vary even with a slight change of the temperature. This causes variation in finished dimension of the workpieces having undergone the plasma processing.

### SUMMARY OF THE INVENTION

The present invention is made to solve the above-described problems. An object of the present invention is to provide a plasma processing apparatus with reduced contamination in a reaction chamber and less variation in shape of workpieces. Another object of the present invention is to provide a processing method using such a plasma processing apparatus. Yet another object of the present invention is to provide a manufacturing method of a semiconductor device suffering less contamination in plasma processing.

The plasma processing apparatus according to an aspect of the present invention generates plasma in a reaction chamber and performs plasma processing on a semiconductor substrate introduced into the reaction chamber. A portion of the reaction chamber exposed to the plasma is provided with a member containing platinum.

With this configuration, the member containing platinum is provided to the portion of the chamber exposed to the plasma. Thus, sputtering of the plasma causes elimination of the platinum, so that the platinum is supplied within the reaction chamber. With reductive catalysis of the platinum, deposition of reactive products generated during the plasma processing onto the inner wall of the chamber, and hence, adhesion of the reactive products to the semiconductor substrate is restricted. This improves the yield of the semiconductor devices. In addition, when the plasma processing is adapted for etching, variation in finished dimension of the pattern can also be restricted.

Preferably, the plasma processing apparatus is provided with a stage portion on which the semiconductor substrate is rested, and a ring-shaped member formed around the stage portion to cover an outer edge thereof. The aforementioned member containing platinum is preferably adapted to this ring-shaped member.

The ring-shaped member is located closest to the semiconductor substrate exposed to the plasma. By employing the member containing platinum as this ring-shaped member, catalytic platinum is readily supplied within the reaction chamber.

More preferably, the ring-shaped member is made of quartz and the quartz contains the platinum.

Still preferably, the inner wall of the reaction chamber is covered with the member containing platinum, since it is also exposed to the plasma.

This facilitates the supply of the platinum as the catalyst within the reaction chamber.

The plasma processing method according to another aspect of the present invention uses a plasma processing apparatus to process a prescribed film formed on a semiconductor substrate by performing plasma processing on the prescribed film. The plasma processing is performed under the condition that a member containing platinum is provided to a portion of a reaction chamber of the plasma processing apparatus that is exposed to plasma being generated therein.

With such a plasma processing method, the plasma processing is performed by providing the member containing platinum to a portion of the chamber exposed to the plasma. Thus, during the plasma processing, elimination of the platinum occurs due to sputtering, so that the platinum is supplied within the reaction chamber. This restricts deposition of reactive products generated during the plasma processing onto the inner wall of the chamber or the like, by virtue of reductive catalysis of the platinum. As a result, adhesion of the reactive products onto the semiconductor substrate is restricted, so that the yield of the semiconductor devices is improved. When this plasma processing is adapted to etching, variation in finished dimension of the pattern is also restricted.

Preferably, the plasma processing is performed adapting the member containing platinum to a ring-shaped member that is formed around a stage portion, for resting the semiconductor substrate thereon, to cover an outer edge of the stage portion.

Further, the plasma processing is preferably performed with the inner wall of the reaction chamber being covered with the member containing platinum.

Accordingly, the platinum as the catalyst can be readily provided into the reaction chamber.

The manufacturing method of a semiconductor device according to yet another aspect of the present invention includes a plasma processing step wherein a prescribed film formed on a semiconductor substrate is subjected to plasma processing. Specifically, in the plasma processing step, a substrate with platinum deposited thereon is subjected to the plasma processing prior to the plasma processing of the prescribed film formed on the semiconductor substrate.

With such a manufacturing method of the semiconductor device, the substrate with platinum deposited thereon first undergoes the plasma processing, so that catalytic platinum is provided into the reaction chamber. Thus, deposition of reactive products, generated during the plasma processing of the prescribed film formed on the semiconductor substrate, onto the chamber inner wall or the like is restricted, and therefore, adhesion of the reactive products to the semiconductor substrate is restricted correspondingly. As a result, the yield of the semiconductor devices is improved.

Preferably, the method includes, prior to the plasma processing step, the step of forming a silicon oxide film as the prescribed film and the step of forming a resist pattern on the silicon oxide film, and, in the plasma processing step, the prescribed film is processed using the resist pattern as a mask.

In this case, adhesion of the reactive products to the semiconductor substrate is restricted, and variation in dimension of the pattern formed to the prescribed film after processing is also restricted.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross sectional view of the plasma processing apparatus according to a first embodiment of the present invention.

FIG. 2 shows an evaluation result of the polymer deposition rate onto the chamber inner wall in the case of the plasma processing apparatus shown in FIG. 1 of the first embodiment, compared to the case of a conventional plasma processing apparatus.

FIG. 3 is a cross sectional view of the plasma processing apparatus according to a second embodiment of the present invention.

FIG. 4 shows semiconductor substrates in one lot and another semiconductor substrate having platinum thereon, for illustration of the manufacturing method of a semiconductor device according to a third embodiment of the present invention.

FIGS. 5-7 are cross sectional views illustrating successive steps of manufacturing the semiconductor device according to the third embodiment.

### DESCRIPTION OF THE PREFERRED EMBODIMENTS

First Embodiment

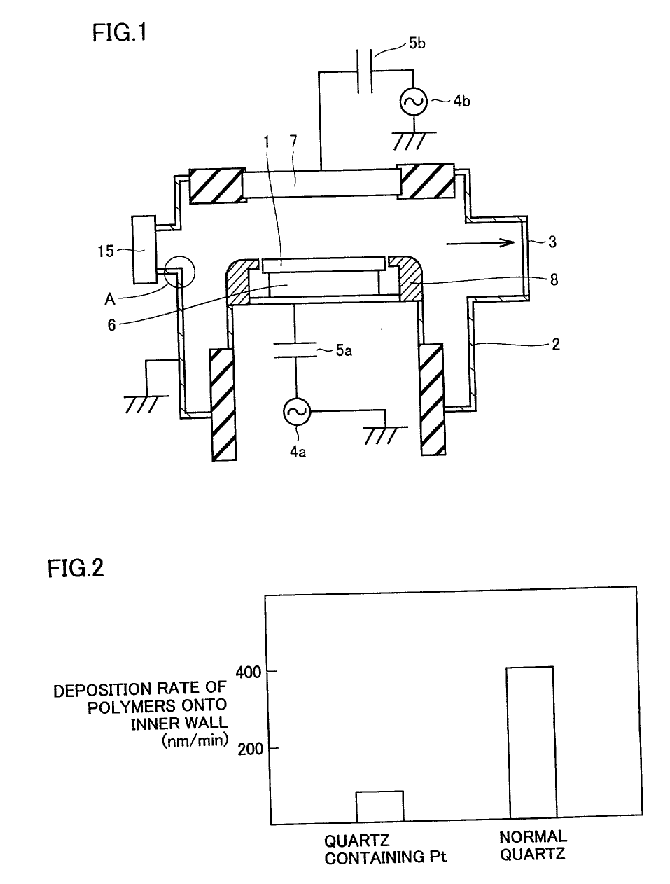

The plasma processing apparatus according to the first embodiment will now be described. Referring to FIG. 1, the plasma processing apparatus includes a chamber 2 wherein plasma processing is performed. In chamber 2, an upper electrode 7 and a lower electrode 6 for discharging plasma into chamber 2 are placed to face to each other. Lower electrode 6 also serves as a stage portion on which a semiconductor substrate 1 is rested. Further, lower electrode 6 is connected via a matching unit 5a to a high-frequency power supply (rf power supply) 4a. Upper electrode 7 is connected via a matching unit 5b to a high-frequency power supply 4b.

In chamber 2, a ring-shaped holding member 8 is also provided which holds semiconductor substrate 1 rested on lower electrode 6.

Further, a gate valve 15 is provided on a side of chamber 2 for letting a wafer in and out of chamber 2. The gas within chamber 2 is discharged via an outlet 3 by a vacuum pump (not shown) or the like.

With this plasma processing apparatus, holding member 8 is formed of quartz containing platinum (Pt).

An example of plasma processing employing the plasma processing apparatus described above will now be described. Here, a silicon oxide film 21 is formed on semiconductor substrate 1 of, e.g., silicon wafer (see FIG. 5), and a prescribed photoresist 22 is formed on the silicon oxide film 21.

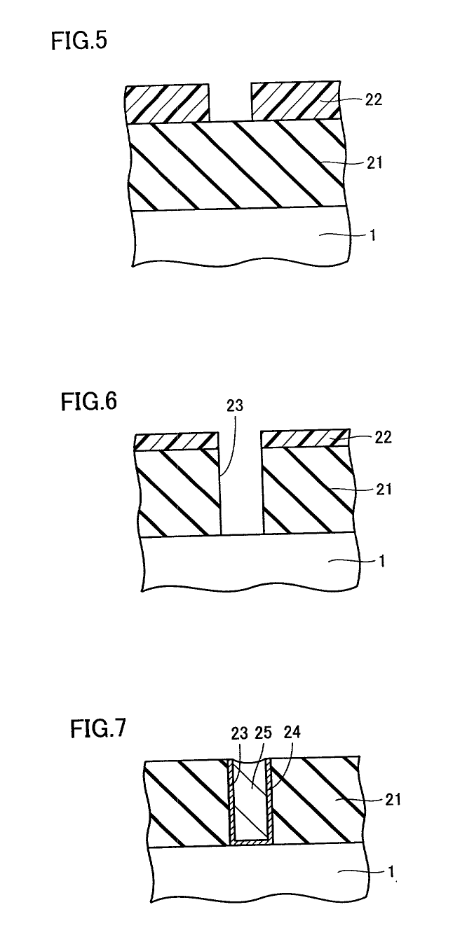

Semiconductor substrate 1 with silicon oxide film 21 and photoresist 22 formed thereon is rested on lower electrode 6 in chamber 2. Using, e.g., a gas containing C₅F₈, O₂ and Ar or a gas containing C₄F₈, O₂ and Ar as an etching gas, plasma is generated within chamber 2, under, e.g., pressure of approximately 2 Pa, power of upper electrode 7 of 2000 W and power of lower electrode 6 of 1500 W, to dissociate the etching gas. Silicon oxide film 21 is thus subjected to etching, with photoresist 22 used as a mask, to form an opening 23 (see FIG. 6).

Appropriate over-etching is applied after the surface of semiconductor substrate 1 is exposed at the bottom of opening 23, and semiconductor substrate 1 is taken out of chamber 2. Thus, the plasma processing (etching) by the plasma processing apparatus is completed.

During the plasma processing described above, the plasma is generated between semiconductor substrate 1 and upper electrode 7. Since the holding member 8 placed around semiconductor substrate 1 is close to the area where the plasma is being generated, holding member 8 is easily exposed to the plasma.

As this holding member 8 is formed of quartz containing platinum, as described above, sputtering by the plasma causes elimination of the platinum contained therein, and the platinum is provided into chamber 2. Thus, by virtue of reductive catalysis of the platinum, deposition of the CFₓ type polymers onto the inner wall of chamber 2 is restricted.

A comparison evaluation was made, regarding the deposition rate of polymers onto the inner wall of chamber 2, between the plasma processing apparatus of the present embodiment and a conventional plasma processing apparatus. In the conventional plasma processing apparatus, the holding member is formed of quartz not containing platinum. Evaluation was made for the polymers deposited on a portion of the chamber inner wall indicated by A in FIG. 1. FIG. 2 shows the evaluation results.

As shown in FIG. 2, with the conventional plasma processing apparatus, the polymer deposition rate onto the chamber inner wall was approximately 400 nm/min. With the plasma processing apparatus of the present embodiment employing the holding member containing platinum, the polymer deposition rate onto the chamber inner wall was approximately 80 nm/min. It means that the speed of adhesion of the polymers to the chamber inner wall of the plasma processing apparatus of the present embodiment is reduced to about one fifth of that of the conventional plasma processing apparatus, by virtue of the catalysis of the platinum.

Thus, with the plasma processing apparatus of the present embodiment, compared to the case of the conventional plasma processing apparatus, the possibility that the polymers deposited on the inner wall of chamber 2 will be stripped off the wall and fall onto semiconductor substrate 1 is limited considerably. This improves the yield of the semiconductor devices formed on semiconductor substrates 1. Variation in finished dimension of, e.g., apertures of openings 23 after etching is also restricted.

Second Embodiment

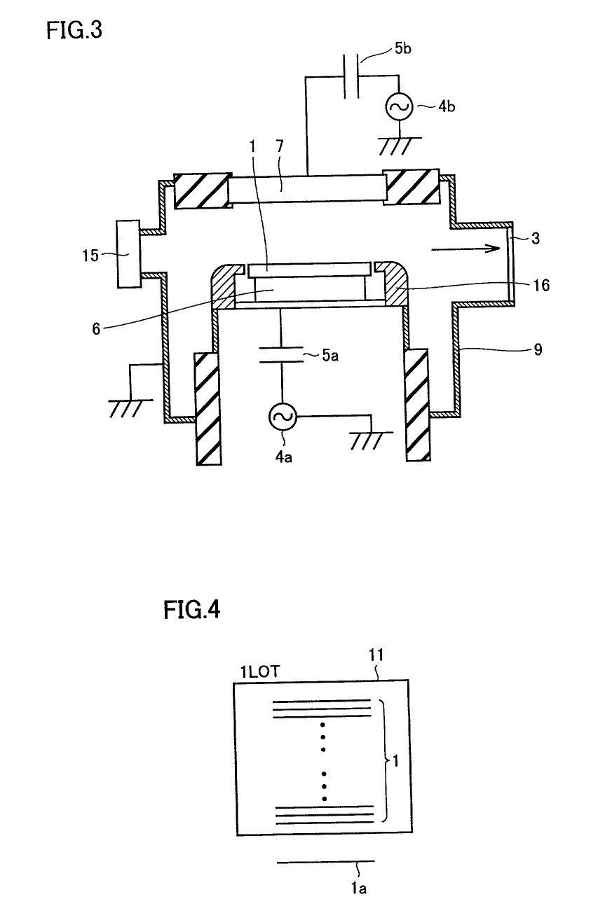

The plasma processing apparatus according to the second embodiment will now be described. Referring to FIG. 3, with this plasma processing apparatus, platinum is contained in the inner wall of the chamber 9. The holding member 16 is formed of quartz, which may also contain platinum. Otherwise, the configuration of the plasma processing apparatus of the second embodiment is identical to that of the first embodiment shown in FIG. 1, and thus, the same or corresponding components are denoted by the same reference character, and detailed description thereof is not repeated.

The inner wall of chamber 9 is also exposed to the plasma generated between upper electrode 7 and substrate 1. At this time, since the inner wall of chamber 9 contains platinum, plasma sputtering causes elimination of the platinum, so that the platinum is provided into chamber 9.

Thus, as described above, deposition of the CFₓ type polymers on the inner wall of chamber 9 is restricted by the reductive catalysis of the platinum. Since the polymer deposition is restricted, compared to the case of the conventional plasma processing apparatus, it is less likely that the polymers accumulated on the inner wall of chamber 9 will be stripped off the wall and fall onto semiconductor substrate 1. Accordingly, the yield of the semiconductor devices formed on semiconductor substrates 1 is improved. Variation in finished dimension after etching is also restricted.

Although the case where platinum is contained in the chamber inner wall has been described, the effects as described above can be achieved if the chamber inner wall is at least covered with a member containing platinum.

Third Embodiment

The manufacturing method of a semiconductor device according to the third embodiment will now be described. In the first and second embodiments above, the case was described wherein platinum contained in the holding member placed within the chamber of the plasma processing apparatus or platinum contained in the inner wall of the chamber was provided into the chamber by plasma sputtering, and catalysis of the platinum worked to restrict the deposition rate of polymers onto the chamber inner wall.

In the present embodiment, the manufacturing method of the semiconductor device is described which utilizes this catalysis of the platinum even in a conventional plasma processing apparatus, to restrict deposition of polymers. As an example of such a manufacturing method of the semiconductor device, the case of forming a plug in a silicon oxide film will now be described.

For manufacturing semiconductor devices formed on semiconductor substrates 1, normally a prescribed number of semiconductor substrates 1 placed in a cassette 11 as one lot, as shown in FIG. 4, are subjected to processing sequentially.

First, a silicon oxide film 21 is formed on the surface of each semiconductor substrate 1, as shown in FIG. 5. A photoresist 22 is then formed on the silicon oxide film 21 for formation of, e.g., an opening (contact hole or the like).

The semiconductor substrates 1 of one lot are then subjected to plasma processing. At this time, prior to the processing of the first semiconductor substrate 1, another semiconductor substrate 1a with platinum deposited thereon, as shown in FIG. 4, is introduced into a chamber of a plasma processing apparatus. As the plasma processing apparatus, a conventional plasma processing apparatus which does not contain platinum in holding member 8 or in the inner wall of chamber 9 in FIGS. 1 or 3 can be employed.

When semiconductor substrate 1a with the platinum deposited thereon is subjected to the plasma processing, the platinum is supplied into the chamber, by plasma sputtering, and adhered to the chamber inner wall and others. The semiconductor substrate la is taken out of the chamber after the plasma processing.

For the plasma processing of semiconductor substrate 1a, any conditions are available as long as they can cause plasma sputtering to provide platinum into the chamber and make the platinum adhere to the chamber inner wall and others. For example, the same conditions as in the subsequent plasma processing for semiconductor substrates 1 may be employed.

The first one of the semiconductor substrates 1 in the lot is now introduced into the chamber. Using a gas containing C₄F₈, O₂ and Ar, for example, and under pressure of approximately 2 Pa, power of the upper electrode of 1800 W and power of the lower electrode of 1500 W, plasma is generated within the chamber to dissociate the etching gas. Semiconductor substrate 1 is thus subjected to the plasma processing.

Accordingly, as shown in FIG. 6, silicon oxide film 21 formed on semiconductor substrate 1 is etched, using photoresist 22 as a mask, to form opening 23.

Thereafter, the first semiconductor substrate 1 is taken out of the chamber. A next semiconductor substrate 1 is then introduced into the chamber and subjected to the identical plasma processing to form opening 23 in silicon oxide film 21. The plasma processing is repeated for the remaining semiconductor substrates 1 in the lot to form openings 23 in respective silicon oxide films 21.

After completion of the plasma processing for the entire lot of semiconductor substrates 1, a next step is conducted. That is, a barrier metal 24 is formed within opening 23, and then tungsten 25 is plugged into the opening 23, so that a plug containing tungsten 25 is formed.

With the manufacturing method of the semiconductor device described above, the plasma processing apparatus performs plasma processing on semiconductor substrate 1a with platinum deposited thereon before the plasma processing of semiconductor substrates 1 in a lot. Accordingly, the platinum is adhered to the chamber inner wall.

Thus, during the plasma processing of the lot of semiconductor substrates 1, plasma sputtering causes elimination of the platinum adhered to the chamber inner wall, and the platinum is supplied into the chamber. This restricts deposition of the CFx type polymers on the chamber inner wall, by virtue of the reductive catalysis of the platinum.

Such restriction of the polymer deposition avoids the possibility of the polymers deposited on the chamber inner wall being stripped off the wall and falling onto semiconductor substrate 1. Accordingly, the yield of the semiconductor devices formed on semiconductor substrates 1 is improved. Further, variation in finished dimension of the openings after etching is also restricted.

In the description above of the plasma processing of the semiconductor device manufacturing method of the present embodiment, formation of opening 23 in silicon oxide film 21 has been described. However, such an opening may be formed in, e.g., a silicon nitride film.

For formation of an opening in the silicon nitride film, it is desirable that a gas including CHF3 and Ar, for example, is employed as an etching gas, and platinum is generated within the chamber, under pressure of approximately 4 Pa, power of the upper electrode of 1600 W and power of the lower electrode of 1000 W, to dissociate the etching gas. Thus, the semiconductor substrate is subjected to plasma processing.

In this case, again, a semiconductor substrate with platinum deposited thereon is first subjected to the plasma processing, so that the platinum is provided within the chamber. This restricts deposition of the polymers onto the chamber inner wall, by virtue of the reductive catalysis of the platinum, and hence restricts falling of the polymers onto the semiconductor substrate. Accordingly, the yield of the semiconductor devices formed on the semiconductor substrates is improved. Variation in finished dimension after etching is also restricted.

The platinum existing within the chamber is gradually decreased, as it is exhausted while the plasma processing of the semiconductor substrates proceeds. Thus, it is preferred to perform the plasma processing on a substrate having platinum deposited thereon, prior to the processing of every lot of semiconductor substrates, to provide the platinum into the chamber.

In some late plasma processing apparatuses, a port has been prepared for processing a dummy substrate prior to the processing of semiconductor substrates in a lot. In such a case, the substrate having platinum deposited thereon may be subjected to the plasma processing as the dummy substrate, which facilitates the supply of the platinum into the chamber.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A plasma processing apparatus generating plasma in a reaction chamber and performing plasma processing on a semiconductor substrate introduced into the reaction chamber, having a member containing platinum being provided to a portion of said reaction chamber that is exposed to the plasma.

2. The plasma processing apparatus according to claim 1, comprising:
a stage portion on which the semiconductor substrate is rested; and
a ring-shaped member formed around said stage portion to cover an outer edge of said stage portion;
wherein said member containing platinum is employed as said ring-shaped member.

3. The plasma processing apparatus according to claim 2, wherein said ring-shaped member is made of quartz and the quarts contains the platinum.

4. The plasma processing apparatus according to claim 3, wherein said member containing platinum covers an inner wall of said reaction chamber.

5. The plasma processing apparatus according to claim 2, wherein said member containing platinum covers an inner wall of said reaction chamber.

6. The plasma processing apparatus according to claim 1, wherein said member containing platinum covers an inner wall of said reaction chamber.

7. A plasma processing method using a plasma processing apparatus to process a prescribed film formed on a semiconductor substrate by performing plasma processing on the prescribed film, said plasma processing being performed under a condition that a member containing platinum is provided to a portion of a reaction chamber of the plasma processing apparatus that is exposed to plasma generated within the chamber.

8. The plasma processing method according to claim 7, wherein the plasma processing is performed employing said member containing platinum as a ring-shaped member that is formed around a stage portion on which the semiconductor substrate is rested, to cover an outer edge of the stage portion.

9. The plasma processing method according to claim 8, wherein the plasma processing is performed with an inner wall of the reaction chamber being covered with said member containing platinum.

10. The plasma processing method according to claim 7, wherein the plasma processing is performed with an inner wall of the reaction chamber being covered with said member containing platinum.

11. A manufacturing method of a semiconductor device, comprising a plasma processing step of performing plasma processing on a prescribed film formed on a semiconductor substrate, said plasma processing step including the step of performing the plasma processing on a substrate with platinum formed thereon prior to the plasma processing of said prescribed film formed on said semiconductor substrate.

12. The manufacturing method of a semiconductor device according to claim 11, comprising, prior to said plasma processing step, the steps of:
forming a silicon oxide film as said prescribed film; and
forming a resist pattern on said silicon oxide film;
wherein said plasma processing step includes the step of processing said prescribed film using said resist pattern as a mask.
